(19) United States
(12) Patent Application Publication
(10) Pub. No.: US 2007/0108530 A1
(43) Pub. Date: May 17, 2007

(54) Semiconductor device and method for manufacturing the same

(76) Inventors: Hisashi Ogawa, Osaka (JP); Yasushi Naito, Osaka (JP); Chiaki Kudo, Hyogo (JP)

Correspondence Address: MCDERMOTT WILL & EMERY LLP, 600 13TH STREET, N.W., WASHINGTON, DC, 20005-3096, US

(21) Appl. No.: 11/543,223

(22) Filed: Oct. 5, 2006

(30) Foreign Application Priority Data
Nov. 15, 2005 (JP) 2005-329682

(51) Int. Cl. H01L 29/94; H01L 21/8238

(52) U.S. Cl. 257/369; 438/199; 257/E27.062

(57) ABSTRACT

A semiconductor device includes a MIS transistor formed in a region of a semiconductor region. The MIS transistor includes a gate insulating film formed on the region, a gate electrode formed on the gate insulating film and fully silicided with metal, source/drain regions formed in parts of the region on the sides of the gate electrode and an insulating film formed to cover the gate electrode and the source/drain regions to cause stress strain in part of the region below the gate electrode.

### CROSS-REFERENCE TO RELATED APPLICATION

This non-provisional application claims priority under 35 U.S.C. § 119(a) of Japanese Patent Application No. 2005-329682 filed in Japan on Nov. 15, 2005, the entire contents of which are hereby incorporated by reference.

### BACKGROUND OF THE INVENTION

1. Field of the Invention

The present invention relates to a semiconductor device and a method for manufacturing the same. In particular, it relates to a semiconductor device having fully silicided (FUSI) gate electrodes and a method for manufacturing the same.

2. Description of Related Art

In the field of CMIS (complementary metal-insulator-semiconductor) devices whose geometries have been getting finer and finer in recent years, eager studies have been made on metal gate electrodes for the purpose of preventing depletion in the gate electrodes. Among them, there has been proposed a fully silicided (FUSI) gate electrode which is a silicide electrode obtained by fully siliciding a polysilicon gate electrode.

Hereinafter, explanation of a first example of a conventional semiconductor device and a method for manufacturing the same is provided with reference to FIGS. 12A to 12C (e.g., see Literature 1 “IEDM Tech. Dig. 2004, pp. 95-98”). As shown in FIG. 12A, an isolation region 102 is formed in a semiconductor substrate 101 to divide the substrate into an NMIS region A for forming an n-type MIS transistor and a PMIS region B for forming a p-type MIS transistor.

First, gate insulating films 103A and 103B and gate silicon films 104A and 104B as gate material are formed in this order on the NMIS region A and the PMIS region B of the semiconductor substrate 101, respectively, followed by patterning. Then, n-type extension regions 105A and p-type extension regions 105B are formed in the semiconductor substrate 101 using the patterned gate silicon films 104A and 104B as a mask. Then, insulating sidewalls 106 are formed on the side surfaces of the gate silicon films 104A and 104B and the gate insulating films 103A and 103B. Then, n-type source/drain regions 107A and p-type source/drain regions 107B are formed in the semiconductor substrate 101 using the gate silicon films 104A and 104B and the sidewalls 106 as a mask. Then, upper portions of the n-type source/drain regions 107A and the p-type source/drain regions 107B exposed on the semiconductor substrate 101 are silicided with nickel or the like to form silicide films 107a and 107b. Then, an insulating etch stopper 108 and an interlayer insulating film 109 are deposited on the entire surface of the semiconductor substrate 101 to cover the gate silicon films 104A and 104B and the sidewalls 106. The top surface of the deposited interlayer insulating film 109 is polished until the gate silicon films 104A and 104B are exposed.

Subsequently, a resist pattern 110 is formed to cover the interlayer insulating film 109 in the NMIS region A and an upper portion of the gate silicon film 104B in the PMIS region B is removed by etching as shown in FIG. 12B.

Then, in the step shown in FIG. 12C, the resist pattern 110 is removed and the gate silicon films 104A and 104B are fully silicided with nickel to form a silicide gate electrode 114A in the NMIS region A and a silicide gate electrode 114B in the PMIS region B. In the first conventional semiconductor device, the silicide gate electrode 114B in the PMIS region B contains a larger amount of nickel as compared with the silicide gate electrode 114A in the NMIS region A because the amount of polysilicon to be reacted with nickel has been reduced before the reaction.

For the purpose of improving drivability of a MIS transistor, a second example of the conventional semiconductor device employs a structure in which the transistor is covered with an insulating film having high stress to cause stress strain in a channel region in the semiconductor substrate below the gate electrode. For example, according to Literature 2 “IEDM Tech Dig. 2004, pp. 213-216”, an n-type MIS transistor is covered with a silicon nitride film having tensile stress and a p-type MIS transistor is covered with a silicon nitride film having compressive stress such that stress strain occurs in the channel regions to improve the transistor characteristic. According to the Literature 2, gate electrodes are not fully silicided.

Hereinafter, in the specification, an insulating film which causes stress strain in the channel region of the transistor is referred to as a stressor film.

According to the method for manufacturing the first conventional semiconductor device, however, the silicide formation for forming the FUSI silicide gate electrodes 114A and 114B is performed after the formation of the gate silicon films 104A and 104B with the upper portions of the gate silicon films 104A and 104B exposed. Therefore, the silicide gate electrodes 114A and 114B cannot be covered with the stressor film as in the second conventional device.

### SUMMARY OF THE INVENTION

In view of the above, an object of the present invention is to form a stressor film effectively even in a semiconductor device having FUSI gate electrodes, thereby improving the electric property of the semiconductor device.

In order to achieve the object, a semiconductor device and a method for manufacturing the same according to the present invention are conceived such that a fully silicided gate electrode of a transistor is completely covered with a stressor film.

To be more specific, the present invention is directed to a semiconductor device including a first MIS transistor of a first conductivity type in a first region of a semiconductor region. The first MIS transistor includes: a first gate insulating film formed on the first region; a first gate electrode formed on the first gate insulating film and fully silicided with metal; first source/drain regions formed in parts of the first region on the sides of the first gate electrode; and an insulating film formed to cover the first gate electrode and the first source/drain regions to cause stress strain in part of the first region below the first gate electrode.

The semiconductor device of the present invention includes the insulating film (stressor film) which is formed to cover the first gate electrode and the first source/drain regions to cause stress strain in part of the first region below the first gate electrode. Therefore, the stress strain is surely caused in part of the first transistor below the first gate electrode, i.e., a channel region. This makes it possible to improve the electric property of the first transistor.

It is preferred that the semiconductor device of the present invention further includes a second MIS transistor of a second conductivity type formed in a second region of the semiconductor region. The second MIS transistor preferably includes: a second gate insulating film formed on the second region; a second gate electrode formed on the second gate insulating film and fully silicided with metal; second source/drain regions formed in parts of the second region on the sides of the second gate electrode; and the insulating film formed to cover at least the second source/drain regions. With this structure, a complementary MIS (CMIS) transistor is achieved.

As to the semiconductor device of the present invention, it is preferred that the first conductivity type is an n-type and the second conductivity type is a p-type and the stress strain is tensile stress strain.

When the semiconductor device of the present invention includes the second MIS transistor, the first gate electrode and the second gate electrode may have the same silicide composition.

In this case, it is preferred that the first gate insulating film and the second gate insulating film are principally made of silicon, oxygen and nitrogen.

When the semiconductor device of the present invention includes the second MIS transistor, it is preferred that the first gate electrode and the second gate electrode have silicide compositions different from each other and the first gate insulating film and the second gate insulating film are made of a high dielectric substance.

When the semiconductor device of the present invention includes the second MIS transistor, the insulating film may also cover the top surface of the second gate electrode.

When the semiconductor device of the present invention includes the second MIS transistor, it is preferred that the insulating film includes a first insulating film and a second insulating film, only the second insulating film of the first and second insulating films is formed on the first gate electrode and the second gate electrode and both of the first and second insulating films are formed in this order on the first source/drain regions and the second source/drain regions.

When the semiconductor device of the present invention includes the second MIS transistor, the semiconductor device of the present invention may further include first sidewalls formed on the side surfaces of the first gate electrode; and second sidewalls formed on the side surfaces of the second gate electrode, wherein the insulating film includes a first insulating film and a second insulating film, only the second insulating film of the first and second insulating films is formed on the first gate electrode and the second gate electrode, only the second insulating film of the first and second insulating films is formed on the first source/drain regions and the second source/drain regions and both of the first and second insulating films are formed in this order on the side surfaces of the first sidewalls and the second sidewalls.

When the semiconductor device of the present invention includes the second MIS transistor, it is preferred that the insulating film is not formed on the second gate electrode.

When the semiconductor device of the present invention includes the second MIS transistor, it is preferred that the insulating film includes a first insulating film and a second insulating film, only the second insulating film of the first and second insulating films is formed on the first gate electrode, both of the first and second insulating films are formed in this order on the first source/drain regions and only the first insulating film of the first and second insulating films is formed on the second source/drain regions.

When the semiconductor device of the present invention includes the second MIS transistor, it is preferred that the insulating film includes a first insulating film and a second insulating film thinner than the first insulating film, only the first insulating film of the first and second insulating films is formed on the first gate electrode and the first source/drain regions and only the second insulating film of the first and second insulating films is formed on the second source/drain regions.

When the semiconductor device of the present invention includes the second MIS transistor, it is preferred that the semiconductor device of the present invention further includes: first sidewalls formed on the side surfaces of the first gate electrode; and second sidewalls formed on the side surfaces of the second gate electrode, wherein the insulating film includes a first insulating film and a second insulating film thinner than the first insulating film, only the first insulating film of the first and second insulating films is formed on the first gate electrode and the first source/drain regions, both of the second and first insulating films are formed in this order on the side surfaces of the first sidewalls and only the second insulating film of the first and second insulating films is formed on the second source/drain regions and the side surfaces of the second sidewalls.

When the semiconductor device of the present invention includes the second MIS transistor, it is preferred that an interlayer insulating film is formed on the second source/drain regions with the insulating film interposed therebetween and the interlayer insulating film is not formed on the first source/drain regions.

In the semiconductor device of the present invention, it is preferred that the insulating film includes a first insulating film and a second insulating film, only the second insulating film of the first and second insulating films is formed on the first gate electrode and both of the first and second insulating films are formed in this order on the first source/drain regions.

A method for manufacturing a semiconductor device according to the present invention includes the steps of: (a) forming a first gate insulating film on a first region of a semiconductor region; (b) forming a first gate silicon film having a gate pattern on the first gate insulating film; (c) forming first source/drain regions of a first conductivity type in parts of the first region on the sides of the first gate silicon film; (d) depositing a first metal film on the first gate silicon film and performing heat treatment after the step (c) such that the first gate silicon film is fully silicided with the first metal film to become a first gate electrode; and (e) forming an insulating film on the first gate electrode and the first source/drain regions to cause stress strain in the first region.

According to the method of the present invention, the insulating film (stressor film) is formed on the first gate electrode and the first source/drain regions in the first region of the semiconductor region to cause stress strain in the first region. Therefore, the stress strain is surely caused in part of the first transistor below the first gate electrode, i.e., a channel region. This makes it possible to improve the electric property of the first transistor.

In the method of the present invention, it is preferred that a second gate insulating film is formed on a second region of the semiconductor region in the step (a), a second gate silicon film having a gate pattern is formed on the second gate insulating film in the step (b), the step (c) includes the step of forming second source/drain regions in parts of the second region on the sides of the second gate silicon film and the first metal film is deposited on the second gate silicon film and heat treatment is performed in the step (d) such that the second gate silicon film is fully silicided with the first metal to become a second gate electrode.

When the second gate insulating film is formed on the second region of the semiconductor region, it is preferred that the method of the present invention further includes the steps of: (f) forming a first insulating film on the first region and the second region to cause stress strain in the first region; and (g) removing parts of the first insulating film on the first gate silicon film and the second gate silicon film to be performed between the steps (c) and (d), wherein a second insulating film serving as the insulating film is formed in the step (e) to cover the first gate electrode, the second gate electrode, the first source/drain regions and the second source/drain regions. According to this method, even if parts of the first insulating film on the first and second gate silicon films are removed for the purpose of fully siliciding the first and second gate electrodes, the second insulating film serving as the insulating film is formed to cover the first gate electrode, the second gate electrode, the first source/drain regions and the second source/drain regions. Therefore, stress strain is surely caused in part of the first transistor below the first gate electrode, i.e., a channel region.

When the second gate insulating film is formed on the second region of the semiconductor region, it is preferred that the method of the present invention further includes: the steps of (f) forming a first insulating film on the first region and the second region to cause stress strain in the first region and (g) removing parts of the first insulating film on the first gate silicon film and the second gate silicon film to be performed between the steps (c) and (d); and the step of (h) removing parts of the first insulating film on the first region and the second region to be performed between the steps (d) and (e), wherein a second insulating film serving as the insulating film is formed in the step (e) to cover the first gate electrode, the second gate electrode, the first source/drain regions and the second source/drain regions.

When the second gate insulating film is formed on the second region of the semiconductor region, it is preferred that the method of the present invention further includes: the step of (f) forming first sidewalls on the side surfaces of the first gate silicon film and second sidewalls on the side surfaces of the second gate silicon film to be performed between the steps (b) and (c); the steps of (g) forming a first insulating film on the first region and the second region to cause stress strain in the first region and (h) removing parts of the first insulating film on the first gate silicon film and the second gate silicon film to be performed between the steps (c) and (d); and the step of (i) removing parts of the first insulating film on the first source/drain regions and the second source/drain regions such that the first insulating film remains on the side surfaces of the first sidewalls and the second sidewalls to be performed between the steps (d) and (e), wherein a second insulating film serving as the insulating film is formed in the step (e) to cover the first gate electrode, the second gate electrode, the first source/drain regions and the second source/drain regions.

When the second gate insulating film is formed on the second region of the semiconductor region, it is preferred that the method of the present invention further includes: the steps of (f) forming a first insulating film on the first region and the second region to cause stress strain in the first region and forming an interlayer insulating film on the first insulating film, (g) removing parts of the first insulating film and parts of the interlayer insulating film on the first gate silicon film and the second gate silicon film and (h) removing part of the interlayer insulating film on the first region after the step (g) to be performed between the steps (c) and (d), wherein a second insulating film is formed on the first region and the second region and part of the second insulating film formed on the second region is removed in the step (e) to provide the insulating film made of the second insulating film. This method makes it possible to reduce stress strain caused in part of the second transistor below the second gate electrode in the second region of the semiconductor region, i.e., a channel region.

When the second gate insulating film is formed on the second region of the semiconductor region, it is preferred that the method of the present invention further includes: the steps of (f) forming a first insulating film on the first region and the second region to cause stress strain in the first region and forming an interlayer insulating film on the first insulating film, (g) removing parts of the first insulating film and the interlayer insulating film on the first gate silicon film and the second gate silicon film and (h) removing parts of the first insulating film and the interlayer insulating film on the first region after the step (g) to be performed between the steps (c) and (d), wherein a second insulating film is formed on the first region and the second region and part of the second insulating film formed on the second region is removed in the step (e) to provide the insulating film made of the second insulating film.

When the second gate insulating film is formed on the second region of the semiconductor region, it is preferred that the method of the present invention further includes: the step of (f) forming first sidewalls on the side surfaces of the first gate silicon film and second sidewalls on the side surfaces of the second gate silicon film to be performed between the steps (b) and (c); and the steps of (g) forming a first insulating film on the first region and the second region to cause stress strain in the first region and forming an interlayer insulating film on the first insulating film, (h) removing parts of the first insulating film and the interlayer insulating film on the first gate silicon film and the second gate silicon film, (i) removing part of the interlayer insulating film on the first region after the step (h) and (j) removing part of the first insulating film on the first source/drain regions after the step (i) such that the first insulating film remains on the side surfaces of the first sidewalls to be performed between the steps (c) and (d), wherein a second insulating film is formed on the first region and the second region and part of the second insulating film formed on the second region is removed in the step (e) to provide the insulating film made of the second insulating film.

Thus, as described above, the semiconductor device and the method for manufacturing the same according to the present invention make it possible to form the stressor film effectively even if the FUSI gate electrodes are formed in the semiconductor device. This improves the electric property of the semiconductor device, e.g., current drivability.

### BRIEF DESCRIPTION OF THE DRAWINGS

FIG. 1 is a sectional view illustrating a semiconductor device according to a first embodiment of the present invention.

FIGS. 2A to 2D are sectional views illustrating the steps of a method for manufacturing the semiconductor device according to the first embodiment of the present invention.

FIGS. 3A to 3D are sectional views illustrating the steps of the method for manufacturing the semiconductor device according to the first embodiment of the present invention.

FIGS. 4A to 4C are sectional views illustrating the steps of a method for manufacturing a semiconductor device according to a first modification of the first embodiment of the present invention.

FIGS. 5A to 5C are sectional views illustrating the steps of a method for manufacturing a semiconductor device according to a second modification of the first embodiment of the present invention.

FIGS. 6A to 6D are sectional views illustrating the steps of a method for manufacturing a semiconductor device according to a third modification of the first embodiment of the present invention.

FIG. 7 is a sectional view illustrating a semiconductor device according to a second embodiment of the present invention.

FIGS. 8A to 8D are sectional views illustrating the steps of a method for manufacturing the semiconductor device according to the second embodiment of the present invention.

FIGS. 9A and 9B are sectional views illustrating the steps of the method for manufacturing the semiconductor device according to the second embodiment of the present invention.

FIGS. 10A to 10D are sectional views illustrating the steps of a method for manufacturing a semiconductor device according to a first modification of the second embodiment of the present invention.

FIGS. 11A to 11D are sectional views illustrating the steps of a method for manufacturing a semiconductor device according to a second modification of the second embodiment of the present invention.

FIGS. 12A to 12C are sectional views illustrating the steps of a method for manufacturing a first example of a conventional semiconductor device.

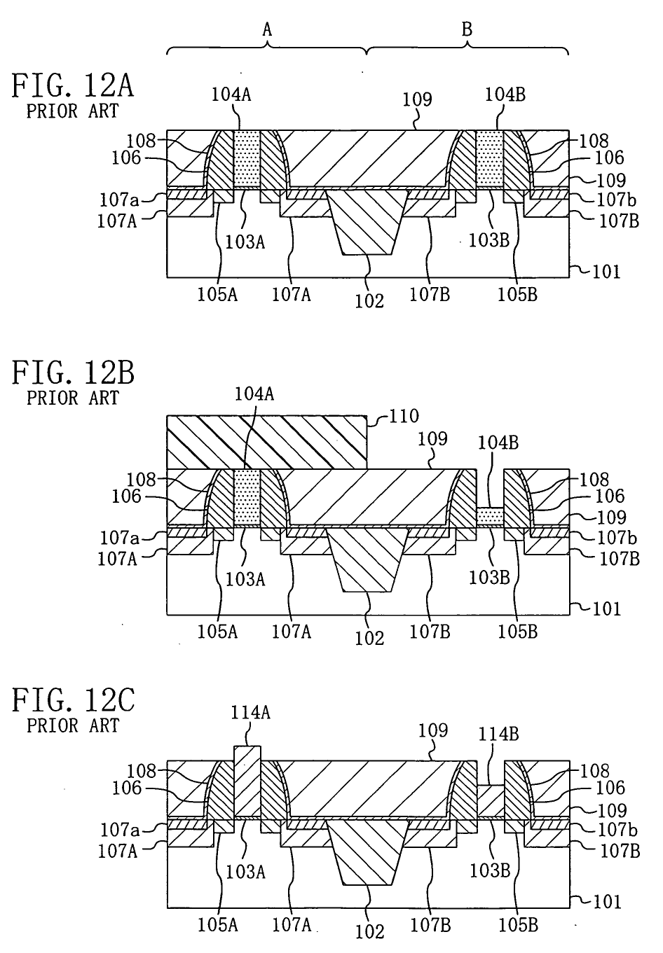

### DETAILED DESCRIPTION OF THE INVENTION

### First Embodiment

With reference to the drawings, explanation of a first embodiment of the present invention is provided.

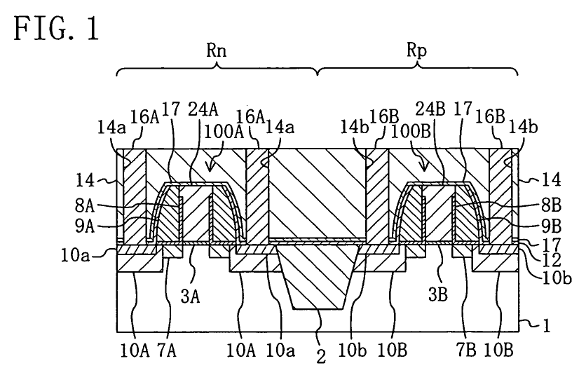

FIG. 1 shows the sectional structure of a semiconductor device according to a first embodiment of the present invention. As shown in FIG. 1, an isolation region 2 formed by shallow trench isolation (STI) to divide a semiconductor substrate 1 made of silicon (Si), for example, into an n-type MIS transistor region Rn and a p-type MIS transistor region Rp.

A MIS transistor 100A formed in the n-type MIS transistor region Rn includes: a gate insulating film 3A formed on a p-well region (not shown) of the semiconductor substrate 1 and made of silicon oxynitride (SiON); a FUSI gate electrode 24A formed on the gate insulating film 3A and fully silicided with nickel (Ni); n-type extension regions 7A formed in the upper portions of the semiconductor substrate 1 on both sides of the FUSI gate electrode 24A; and n-type source/drain regions 10A formed outside the n-type extension regions 7A to be connected thereto and have a junction deeper than that of the n-type extension regions 7A. Silicide films 10a made of nickel silicide are formed on the n-type source/drain regions 10A.

Likewise, the p-type MIS transistor 100B formed in the p-type MIS transistor region Rp includes: a gate insulating film 3B formed on an n-well region (not shown) of the semiconductor substrate 1 and made of silicon oxynitride: a FUSI gate electrode 24B formed on the gate insulating film 3B and fully silicided with nickel; p-type extension regions 7B formed in the upper portions of the semiconductor substrate 1 on both sides of the FUSI gate electrode 24B; and p-type source/drain regions 10B formed outside the p-type extension regions 7B to be connected thereto and have a junction deeper than that of the p-type extension regions 7B. Silicide films 10b made of nickel silicide are formed on the p-type source/drain regions 10B.

On the side surfaces of the FUSI gate electrodes 24A and 24B parallel to the gate length direction, first sidewalls 8A and 8B which are made of silicon oxide and L-shaped in section are formed, respectively, and second sidewalls 9A and 9B made of silicon nitride (Si₃N₄) are formed on the first sidewalls 8A and 8B, respectively.

On the principle surface of the semiconductor substrate 1 and the outer sides of the second sidewalls 9A and 9B, a first underlayer insulating film 12 made of silicon nitride (Si₃N₄) is formed. Further, a second underlayer insulating film 17 made of silicon nitride is formed on the first underlayer insulating film 12 to cover the exposed top surfaces of the FUSI gate electrodes 24A and 24B and the second sidewalls 9A and 9B. On the FUSI gate electrodes 24A and 24B, the first underlayer insulating film 12 is not formed but the second underlayer insulating film 17 is solely provided.

A second interlayer insulating film 14 made of silicon oxide is formed on the second underlayer insulating film 17 with the top surface thereof planarized. In parts of the second interlayer insulating film 14 above the source/drain regions 10A and 10B, contact plugs 16A and 16B made of a titanium (Ti)/titanium nitride (TiN) layered film and tungsten (W) are formed to be connected to the silicide films 10a and 10b of the source/drain regions 10A and 10B, respectively.

As a feature of the first embodiment, the first underlayer insulating film 12 functions as a stressor film having tensile stress and as an etch stopper for forming contact holes 14a and 14b in the second interlayer insulating film 14 to provide the contact plugs 16A and 16B. In the present specification, a stressor film having tensile stress indicates a film capable of applying tensile stress in the gate length direction to channel regions in the semiconductor substrate 1 immediately below the FUSI gate electrodes 24A and 24B.

Just like the first underlayer insulating film 12, the second underlayer insulating film 17 also functions as a stressor film having tensile stress and as an etch stopper for forming the contact holes 14a and 14b. The second underlayer insulating film 17 is formed on the first underlayer insulating film 12 to cover the second sidewalls 9A and 9B and the FUSI gate electrodes 24A and 24B continuously. Therefore, the second underlayer insulating film 17 makes it possible to apply tensile stress to the channel regions with higher reliability as compared with the non-continuous first underlayer insulating film 12 which does not cover the top surfaces of the FUSI gate electrodes 24A and 24B. As a result, the n-type MIS transistor 100A, in particular, improves in current drivability due to the tensile stress applied to the channel region of the n-type MIS transistor 100A.

Hereinafter, a method for manufacturing the above-described semiconductor device is provided with reference to the drawings.

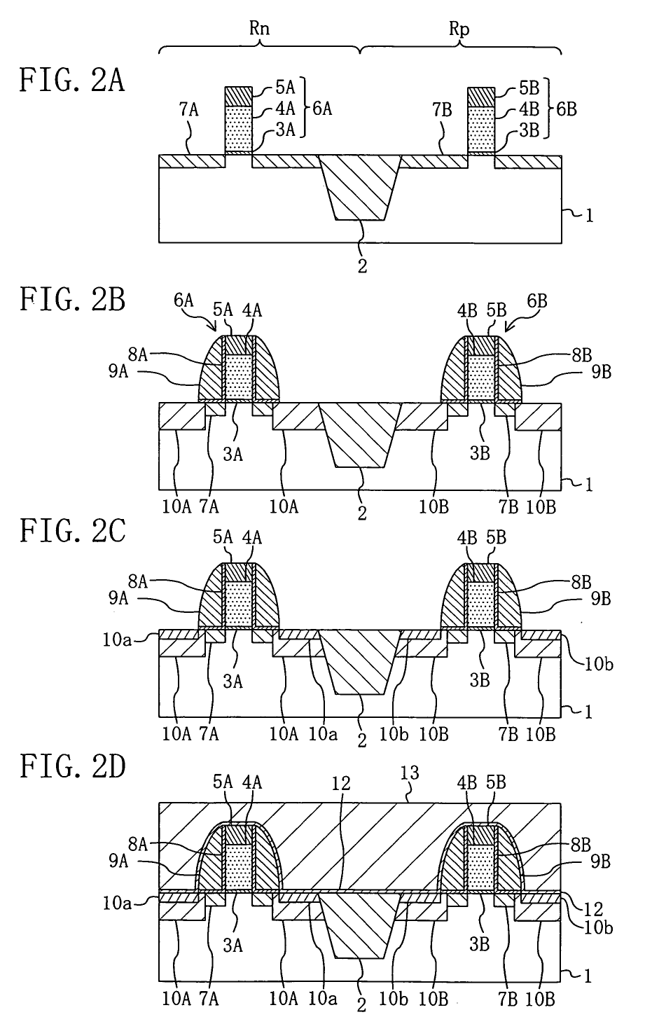

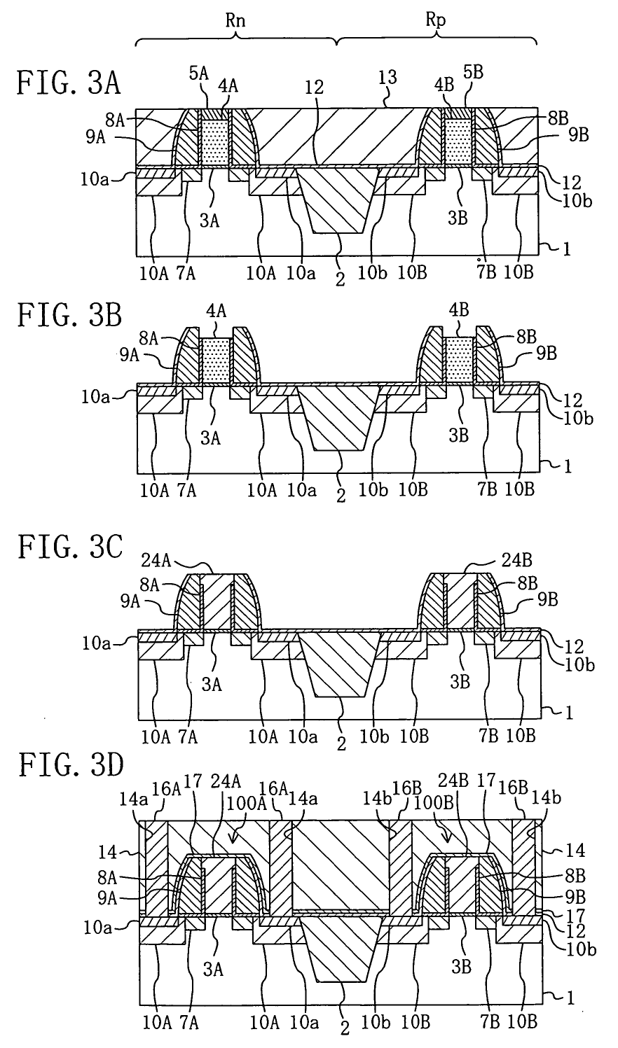

FIGS. 2A to 2D and FIGS. 3A to 3D are sectional views illustrating the steps of the method for manufacturing the semiconductor device according to the first embodiment of the present invention.

First, as shown in FIG. 2A, a shallow trench isolation (STI) region as an isolation region 2 is formed in a semiconductor substrate 1 made of silicon by a general device isolation technique. Thus, the semiconductor substrate 1 is divided into an n-type MIS transistor region Rn as an active region for an n-type MIS transistor and a p-type MIS transistor region Rp as an active region for a p-type MIS transistor. Subsequently, p-type impurity ions are implanted into the n-type MIS transistor region Rn of the semiconductor substrate 1 to form a p-well region (not shown). Further, n-type impurity ions are implanted into the p-type MIS transistor region Rp of the semiconductor substrate 1 to form an n-well region (not shown). The p- and n-well regions may be formed in the reverse order.

Then, a 2 nm thick silicon oxynitride film is formed on the semiconductor substrate 1 as a gate insulating film. A 100 nm thick polysilicon film is formed thereon as a gate silicon film as gate material, and then a silicon oxide film is formed thereon as a protection insulating film for protecting the polysilicon film. The silicon oxynitride film as the gate insulating film may be achieved by forming a silicon oxide film by thermal oxidation and introducing nitrogen into the silicon oxide film by plasma nitridation or subjecting the semiconductor substrate 1 to oxynitridation. Then, the silicon oxide film, polysilicon film and silicon oxynitride film are successively subjected to lithography and anisotropic dry etching to form the silicon oxynitride film into gate insulating films 3A and 3B, the polysilicon film into gate silicon films 4A and 4B and the silicon oxide film into gate protection insulating films 5A and 5B for protecting the gate silicon films 4A and 4B. The silicon oxide film and the silicon oxynitride film are etched using etching gas mainly consisted of fluorocarbon and the polysilicon film is etched using etching gas mainly consisted of chlorine or hydrogen bromide. Accordingly, an n-type gate precursor stack 6A including the gate insulating film 3A, gate silicon film 4A and gate protection insulating film 5A is provided on the n-type MIS transistor region Rn of the semiconductor substrate 1. At the same time, a p-type gate precursor stack 6B including the gate insulating film 3B, gate silicon film 4B and gate protection insulating film 5B is provided on the p-type MIS transistor region Rp of the semiconductor substrate 1.

Then, n-type impurity ions are implanted into the n-type MIS transistor region Rn of the semiconductor substrate 1 using the n-type gate precursor stack 6A as a mask to form n-type extension regions 7A in parts of the semiconductor substrate 1 on both sides of the n-type gate precursor stack 6A. Thereafter, p-type impurity ions may be implanted into the n-type MIS transistor region Rn of the semiconductor substrate 1 using the n-type gate precursor stack 6A as a mask to form p-type pocket regions (not shown) in the substrate below the n-type extension regions 7A. For example, the n-type extension regions 7A may be formed by implanting arsenic ions at implantation energy of 3 keV and a dose of 1×10¹⁵/cm². Further, the p-type pocket regions may be formed by implanting boron ions at implantation energy of 10 keV and a dose of 1×10¹³/cm².

Subsequently, p-type impurity ions are implanted into the p-type MIS transistor region Rp of the semiconductor substrate 1 using the p-type gate precursor stack 6B as a mask to form p-type extension regions 7B in parts of the semiconductor substrate 1 on both sides of the p-type gate precursor stack 6B. Thereafter, n-type impurity ions may be implanted into the p-type MIS transistor region Rp of the semiconductor substrate 1 using the p-type gate precursor stack 6B as a mask to form n-type pocket regions (not shown) in the substrate below the p-type extension regions 7B. For example, the p-type extension regions 7B may be formed by implanting boron ions at implantation energy of 0.5 keV and a dose of 1×10¹⁴/cm². Further, the n-type pocket regions may be formed by implanting arsenic ions at implantation energy of 30 keV and a dose of 1×10¹³/cm². The order of the formation of n-type extension regions 7A, p-type pocket regions, p-type extension regions 7B and n-type pocket regions is not particularly limited to the described one.

Then, as shown in FIG. 2B, a first insulating film made of a 10 nm thick silicon oxide film is formed on the entire surface of the semiconductor substrate 1 on which the gate precursor stacks 6A and 6B have been formed and a second insulating film made of a 60 nm thick silicon nitride film is formed thereon. Then, the second and first insulating films are anisotropically etched back in this order such that first sidewalls 8A and 8B each having an L-shaped section and made of the first insulating film are formed on the side surfaces of the n-type gate precursor stack 6A and the p-type gate precursor stack 6B, respectively, and second sidewalls 9A and 9B made of the second insulating film are formed on the first sidewalls 8A and 8B, respectively. The provision of the first sidewalls 8A and 8B is not always necessary.

Then, in the n-type MIS transistor region Rn of the semiconductor substrate 1, arsenic ions as n-type impurities are implanted at implantation energy of 10 keV and a dose of 1×10¹⁵/cm² using the n-type gate precursor stack 6A and the sidewalls 8A and 9A as a mask to form n-type source/drain regions 10A in parts of the semiconductor substrate 1 on both sides of the sidewalls 8A and 9A to be connected to the n-type extension regions 7A.

In the p-type MIS transistor region Rp of the semiconductor substrate 1, boron ions as p-type impurities are implanted at implantation energy of 2 keV and a dose of 1×10¹⁵/cm² using the p-type gate precursor stack 6B and the sidewalls 8B and 9B as a mask to form p-type source/drain regions 10B in parts of the semiconductor substrate 1 on both sides of the sidewalls 8B and 9B to be connected to the p-type extension regions 7B.

Then, as shown in FIG. 2C, a 10 nm thick metal film made of nickel (Ni) is formed on the entire surface of the semiconductor substrate 1 by sputtering, for example. The semiconductor substrate 1 provided with the metal film is heated at 500° C. in nitrogen atmosphere for about 20 seconds to cause reaction between the metal film and silicon contacting thereto. As a result, silicide films 10a and 10b are formed selectively in the upper portions of the n-type source/drain regions 10A and the p-type source/drain regions 10B, respectively. Then, the remaining metal film unreacted with silicon is removed by etching using a solution mixture of sulfuric acid and hydrogen peroxide water, for example.

Then, as shown in FIG. 2D, a 10 nm thick silicon nitride film having tensile stress of 2 GPa is formed on the entire surface of the semiconductor substrate 1 by plasma CVD as a first underlayer insulating film 12 covering the n-type gate precursor stack 6A, sidewalls 8A and 9A, p-type gate precursor stack 6B and sidewalls 8B and 9B. Then, a 500 nm thick first interlayer insulating film 13 made of a silicon oxide film added with phosphorus (P) (a PSG film) is formed on the first underlayer insulating film 12 by CVD. In the first embodiment, the first underlayer insulating film 12 is a stressor film having tensile stress and functions as an etch stopper in the step of forming contact holes in a second interlayer insulating film 14 to be formed later.

Then, as shown in FIG. 3A, chemical mechanical polish (CMP) is performed on the first interlayer insulating film 13 to polish away the first interlayer insulating film 13 and the first underlayer insulating film 12 until the gate protection insulating films 5A and 5B are exposed. Thus, the top surfaces of the first interlayer insulating film 13, the first underlayer insulating film 12 and the gate protection insulating films 5A and 5B exposed in the first interlayer insulating film 13 are planarized to be flush with each other.

Then, as shown in FIG. 3B, the gate protection insulating films 5A and 5B made of silicon oxide and the first interlayer insulating film 13 are wet-etched using a hydrogen fluoride (HF) solution to expose the gate silicon films 4A and 4B and remove the first interlayer insulating film 13. The first interlayer insulating film 13 used herein is made of an insulating film which is etched at a higher rate as compared with the gate protection insulating films 5A and 5B, e.g., a PSG film. Therefore, even if the first interlayer insulating film 13 is thicker than the gate protection insulating films 5A and 5B, the first interlayer insulating film 13 is easily removed.

Then, a 100 nm metal film made of nickel (not shown) is formed on the entire surface of the semiconductor substrate 1 by sputtering, for example. The semiconductor substrate 1 provided with the metal film is heated at 400° C. in nitrogen atmosphere to cause reaction between the metal film and polysilicon as the gate silicon films 4A and 4B contacting thereto. As a result, the gate silicon films 4A and 4B are fully silicided to be FUSI gate electrodes 24A and 24B made of nickel silicide. Then, the remaining metal film unreacted is removed by etching using a solution mixture of sulfuric acid and hydrogen peroxide water to achieve the structure shown in FIG. 3C.

Then, as shown in FIG. 3D, a 10 nm thick silicon nitride film having tensile stress of 2 GPa is formed on the entire surface of the semiconductor substrate 1 by plasma CVD as a second underlayer insulating film 17 covering the first underlayer insulating film 12 and the top surfaces of the FUSI gate electrodes 24A and 24B and the second sidewalls 9A and 9B exposed in the first underlayer insulating film 12. Then, a 500 nm thick silicon oxide film free from impurities (non-doped silicate glass: NSG) is formed on the entire surface of the second underlayer insulating film 17 as a second interlayer insulating film 14. Then, the top surface of the second interlayer insulating film 14 is planarized by CMP. Further, parts of the second interlayer insulating film 14, second underlayer insulating film 17 and first underlayer insulating film 12 positioned above the n-type source/drain regions 10A in the n-type MIS transistor region Rp and the p-type source/drain regions 10B in the p-type MIS transistor region Rp are sequentially etched away to form contact holes 14a reaching the silicide films 10a formed in the upper portions of the n-type source/drain regions 10A and contact holes 14b reaching the silicide films 10b formed in the upper portions of the p-type source/drain regions 10B. In this step, first, the second interlayer insulating film 14 is etched using the second underlayer insulating film 17 as an etch stopper to form contact holes penetrating the second interlayer insulating film 14, and then the second and first underlayer insulating films 17 and 12 at the bottom of the contact holes are successively etched away to form the contact holes 14a and 14b. Then, a metal film made of Ti/TiN and W is formed on the second interlayer insulating film 14 and in the contact holes 14a and 14b by CVD. Part of the metal film deposited on the second interlayer insulating film 14 is removed by CMP to form contact plugs 16A and 16B in the contact holes 14a and 14b. Then, metallic interconnection (not shown) to be connected to the contact plugs 16A and 16B is formed on the second interlayer insulating film 14 provided with the contact plugs 16A and 16B.

According to the method for manufacturing the semiconductor device of the first embodiment as described above, the second underlayer insulating film 17 serving as an etch stopper and a stressor film having tensile stress is formed on the first underlayer insulating film 12 to cover the top surfaces of the second sidewalls 9A and 9B and the top surfaces of the FUSI gate electrodes 24A and 24B continuously. As a result, the second underlayer insulating film 17 surely applies tensile stress to the channel region of the n-type MIS transistor 100A. The applied tensile stress improves the current drivability of the n-type MIS transistor 100A.

(First Modification of First Embodiment)

Hereinafter, explanation of a first modification of the first embodiment of the present invention is provided with reference to the drawings.

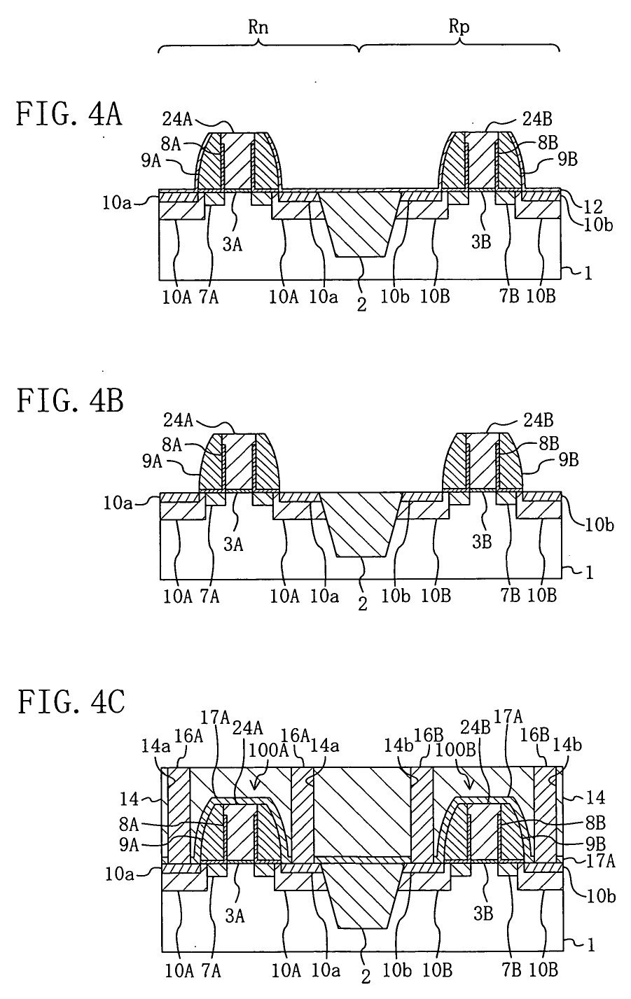

FIGS. 4A to 4C are sectional views illustrating the steps of a method for manufacturing a semiconductor device according to the first modification of the first embodiment of the present invention. In the modifications to be described below, the same components as those shown in FIGS. 2 and 3 are indicated by the same reference numerals.

First, the first interlayer insulating film 13 and the gate protection insulating films 5A and 5B are removed in the same manner as in the first embodiment and the structure provided with the FUSI gate electrodes 24A and 24B as shown in FIG. 4A is obtained.

Then, as shown in FIG. 4B, the first underlayer insulating film 12 is removed by isotropic etching at a low etch rate using etching gas such as tetrafluorocarbon (CF₄).

Then, as shown in FIG. 4C, a 20 nm thick silicon nitride film having tensile stress of 2 GPa is formed on the entire surface of the semiconductor substrate 1 by plasma CVD as a second underlayer insulating film 17A covering the exposed surfaces of the silicide films 10a and 10b, FUSI gate electrodes 24A and 24B and sidewalls 8A, 8B, 9A and 9B. Thereafter, in the same manner as in the first embodiment, a second interlayer insulating film 14 is formed and contact plugs 16A and 16B are formed to be connected to the silicide films 10a and 10b of the source/drain regions 10A and 10B.

Thus, with use of the second underlayer insulating film 17A continuously covering the entire surface of the semiconductor substrate 1, the method of the first modification also makes it possible to provide the same effect as obtained in the first embodiment.

(Second Modification of First Embodiment)

Hereinafter, explanation of a second modification of the first embodiment of the present invention is provided with reference to the drawings.

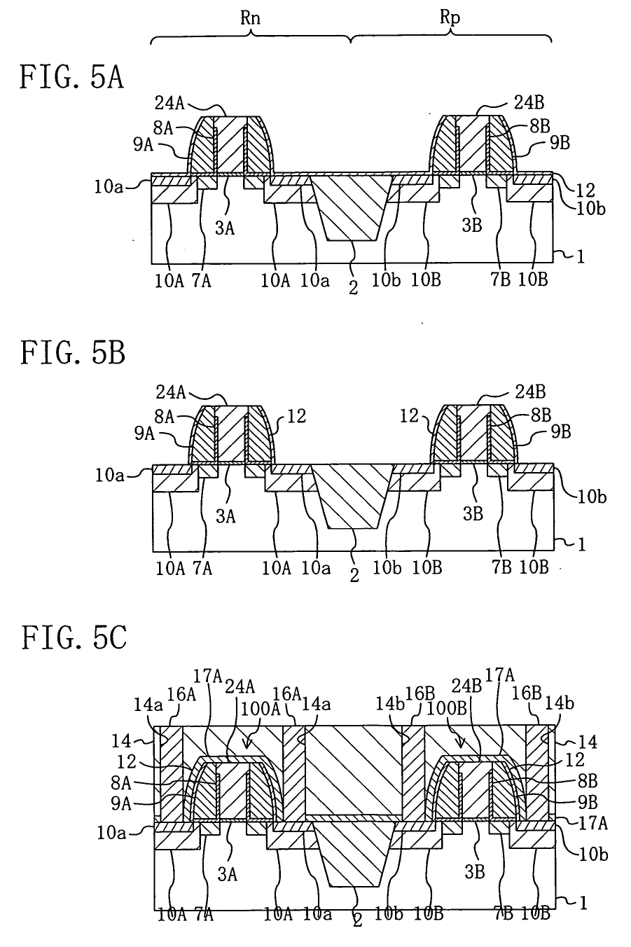

FIGS. 5A to 5C are sectional views illustrating the steps of a method for manufacturing a semiconductor device according to the second modification of the first embodiment of the present invention.

First, the first interlayer insulating film 13 and the gate protection insulating films 5A and 5B are removed in the same manner as in the first embodiment and the structure provided with the FUSI gate electrodes 24A and 24B as shown in FIG. 5A is obtained.

Then, the first underlayer insulating film 12 is partially removed by anisotropic etching using etching gas such as CHF₃ such that the first underlayer insulating film 12 remains on both sides of the second sidewalls 9A and 9B as shown in FIG. 5B.

Then, as shown in FIG. 5C, a 20 nm silicon nitride film having tensile stress of 2 GPa is formed on the entire surface of the semiconductor substrate 1 by plasma CVD as a second underlayer insulating film 17A covering the exposed surfaces of the silicide films 10a and 10b, FUSI gate electrodes 24A and 24B, the second sidewalls 9A and 9B and the first underlayer insulating film 12. Thereafter, in the same manner as in the first embodiment, a second interlayer insulating film 14 is formed and contact plugs 16A and 16B are formed to be connected to the silicide films 10a and 10b of the source/drain regions 10A and 10B.

Thus, with use of the second underlayer insulating film 17A continuously covering the entire surface of the semiconductor substrate 1, the method of the second modification also makes it possible to provide the same effect as obtained in the first embodiment.

(Third Modification of First Embodiment)

Hereinafter, explanation of a third modification of the first embodiment of the present invention is provided with reference to the drawings.

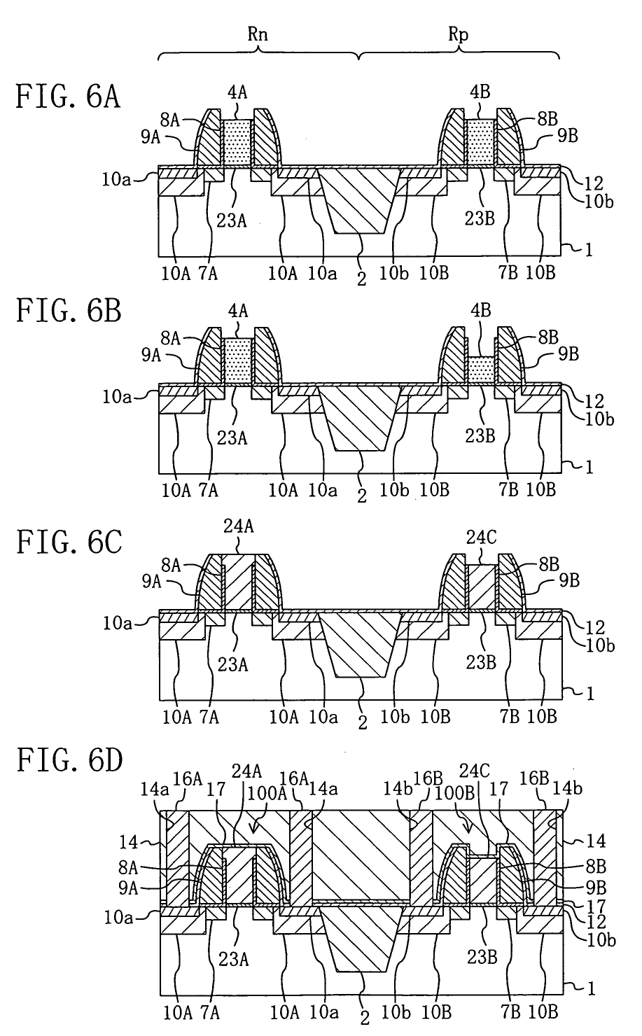

FIGS. 6A to 6D are sectional views illustrating the steps of a method for manufacturing a semiconductor device according to the third modification of the first embodiment of the present invention.

First, the first interlayer insulating film 13 and the gate protection insulating films 5A and 5B are removed in the same manner as in the first embodiment to expose the gate silicon films 4A and 4B as shown in FIG. 6A. In the present modification, the gate insulating films 3A and 3B made of silicon oxynitride are replaced with gate insulating films 23A and 23B which are high dielectric films, i.e., high-k films, made of hafnium oxide (HfO₂) or hafnium nitride silicate (HfSiON). The gate insulating films 23A and 23B are about 2 nm in thickness. A 1 nm thick base layer made of silicon oxide or silicon oxynitride may be formed between the semiconductor substrate 1 and the gate insulating films 23A and 23B.

Then, as shown in FIG. 6B, the gate silicon film 4B in the p-type MIS transistor region Rp is selectively etched to remove the upper portion thereof. For example, 60 nm of the gate silicon film 4B from the top is etched away such that 40 nm of the gate silicon film 4B remains. The gate silicon film 4A in the n-type MIS transistor region Rn which is not etched has a thickness of 100 nm.

Then, a 60 nm thick metal film made of nickel (not shown) is formed on the entire surface of the semiconductor substrate 1 by sputtering, for example. The semiconductor substrate 1 provided with the metal film is heated at 400° C. in nitrogen atmosphere to cause reaction between the metal film and polysilicon as the gate silicon films 4A and 4B contacting thereto. As a result, the gate silicon films 4A and 4B are fully silicided to be FUSI gate electrodes 24A and 24C made of nickel silicide. At this stage, the composition of the FUSI gate electrode 24A in the n-type MIS transistor region Rn is NiSi, while the composition of the FUSI gate electrode 24C in the p-type MIS transistor region Rp is Ni₃Si. Thereafter, the remaining metal film unreacted is removed by etching using a solution mixture of sulfuric acid and hydrogen peroxide water to achieve the structure shown in FIG. 6C.

Then, as shown in FIG. 6D, a second underlayer insulating film 17, a second interlayer insulating film 14 and contact plugs 16A and 16B connected to the silicide films 10a and 10b of the source/drain regions 10A and 10B are formed in the same manner as in the first embodiment.

In the third modification of the first embodiment where the gate insulating films 23A and 23B are made of high dielectric films, the ratio of metal in the FUSI gate electrode 24C in the p-type MIS transistor 100B is set higher than that in the FUSI gate electrode 24A in the n-type MIS transistor 100A. Therefore, the threshold voltage of the p-type MIS transistor 100B can be set to a desired value.

### Second Embodiment

Hereinafter, explanation of a second embodiment of the present invention is provided with reference to the drawings.

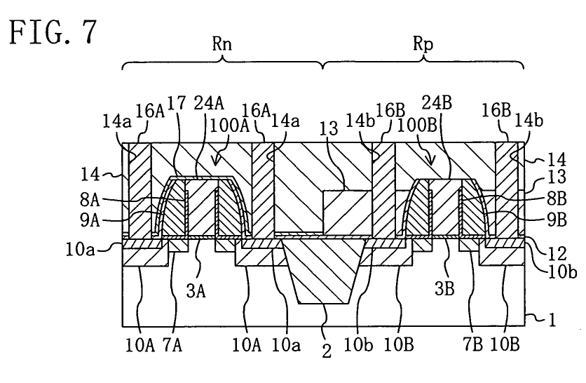

FIG. 7 shows the sectional structure of a semiconductor device according to a second embodiment of the present invention. In FIG. 7, the same components as those shown in FIG. 1 are indicated by the same reference numerals to omit the explanation.

In the second embodiment, as shown in FIG. 7, the second underlayer insulating film 17 is selectively formed to cover only the n-type MIS transistor 100A in the n-type MIS transistor region Rn. Further, the first interlayer insulating film 13 formed on the first underlayer insulating film 12 remains in the p-type MIS transistor region Rp.

The second underlayer insulating film 17 selectively formed in the n-type MIS transistor region Rn functions as a stressor film having tensile stress and an etch stopper in the step of forming the contact holes 14a just like the first underlayer insulating film 12. The second underlayer insulating film 17 is formed on the first underlayer insulating film 12 to cover the top surfaces of the second sidewalls 9A and the FUSI gate electrode 24A continuously. In the step of forming the contact holes 14b, the first underlayer insulating film 12 functions as an etch stopper. Therefore, the second underlayer insulating film 17 applies the tensile stress to the channel region in the n-type MIS transistor region Rn with higher reliability as compared with the first underlayer insulating film 12 formed non-continuously not to cover the top surface of the FUSI gate electrode 24A. The tensile stress applied to the channel region of the n-type MIS transistor 100A improves the current drivability of the n-type MIS transistor 100A.

In the second embodiment, the second underlayer insulating film 17 is selectively formed only in the n-type MIS transistor Rn. This is preferable because tensile stress strain as significant as that in the n-type MIS transistor 100A is not caused in the channel region in the p-type MIS transistor 100B.

Hereinafter, explanation of a method for manufacturing the thus configured semiconductor device is provided with reference to the drawings.

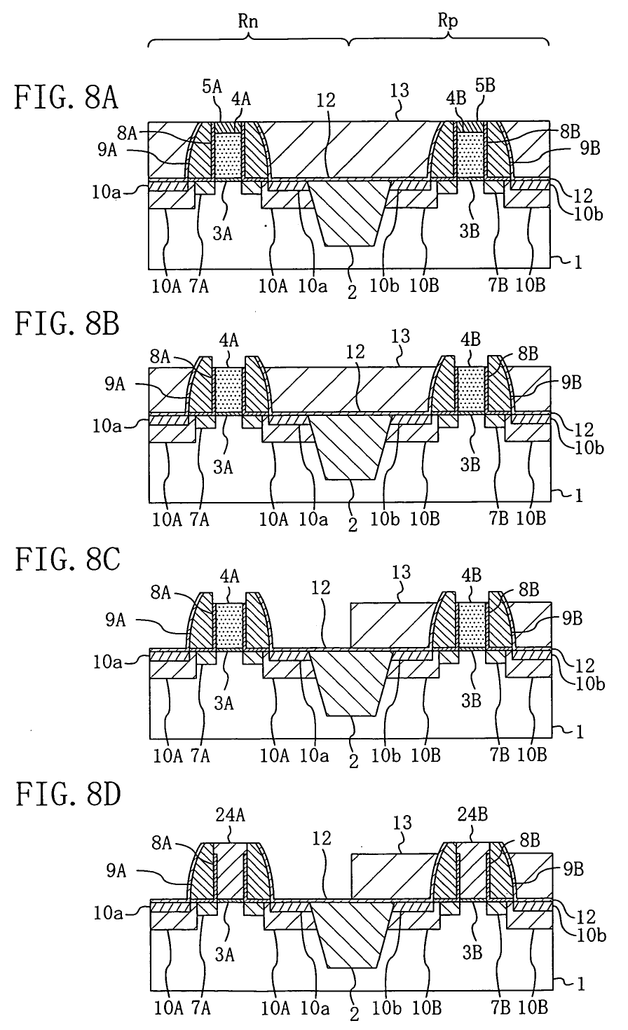

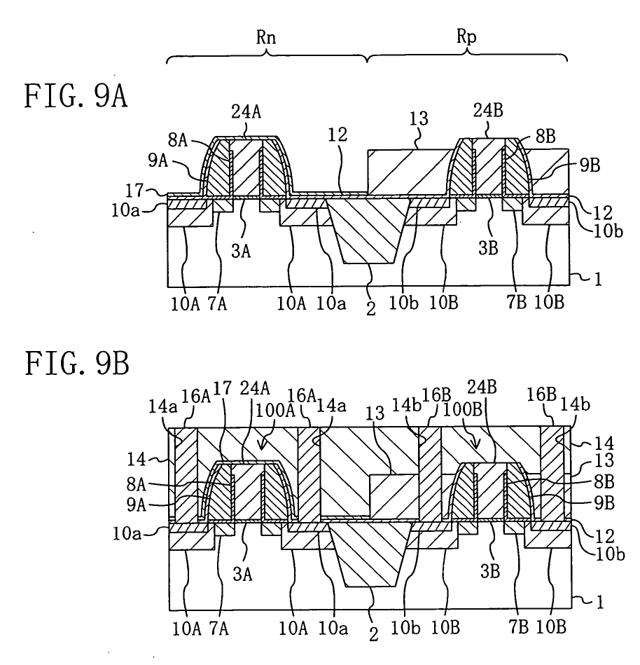

FIGS. 8A to 8D and FIGS. 9A and 9B are sectional views illustrating the steps of the method for manufacturing the semiconductor device according to the second embodiment of the present invention. In FIGS. 8A to 8D and FIGS. 9A and 9B, the same components as those of the first embodiment shown in FIGS. 2 and 3 are indicated by the same reference numerals.

First, the top surface of the first interlayer insulating film 13 is planarized in the same manner as in the first embodiment to expose the gate protection insulating films 5A and 5B out of the first interlayer insulating film 13 as shown in FIG. 8A.

Then, as shown in FIG. 8B, the gate protection insulating films 5A and 5B are removed by wet etching using a hydrogen fluoride solution to expose the gate silicon films 4A and 4B. In this step, the upper portion of the first interlayer insulating film 13 may be etched away.

Then, as shown in FIG. 8C, a first resist film (not shown) having an opening corresponding to the n-type MIS transistor region Rn is formed on the first interlayer insulating film 13 by lithography. The first resist film has the opening at least over the active region of the n-type MIS transistor region Rn. Using the first resist film as a mask, the first interlayer insulating film 13 is wet-etched with a hydrogen fluoride solution to expose part of the first underlayer insulating film 12 corresponding to the active region of the n-type MIS transistor region Rn. Then, the first resist film is removed by ashing or the like. In the second embodiment, the first interlayer insulating film 13 is preferably an insulating film which is etched at a higher rate than the first sidewalls 8A, e.g., a PSG film such that the first sidewalls 8A are prevented from being etched back in the step of etching the first interlayer insulating film 13. In the present embodiment, the first interlayer insulating film 13 is left in the p-type MIS transistor region Rp. However, the first interlayer insulating film 13 may be removed from the p-type MIS transistor region Rp in the same manner as in the first embodiment. In the second embodiment, however, part of the second underlayer insulating film 17 formed in the p-type MIS transistor region Rp is removed in a later step. Therefore, it is preferable to leave the first interlayer insulating film 13 as an etch stopper in the step of removing the second underlayer insulating film 17 by etching.

Then, a 100 nm thick metal film made of nickel (not shown) is formed on the entire surface of the semiconductor substrate 1 by sputtering, for example. The semiconductor substrate 1 provided with the metal film is heated at 400° C. in nitrogen atmosphere to cause reaction between the metal film and polysilicon composing the gate silicon films 4A and 4B contacting thereto. As a result, the gate silicon films 4A and 4B are fully silicided to be FUSI gate electrodes 24A and 24B made of nickel silicide. Then, the remaining metal film unreacted is removed by etching using a solution mixture of sulfuric acid and hydrogen peroxide water to achieve the structure shown in FIG. 8D.

Then, a 10 nm silicon nitride film having tensile stress of 2 GPa is formed on the entire surface of the semiconductor substrate 1 by plasma CVD as a second underlayer insulating film 17 covering the first underlayer insulating film 12 and the top surfaces of the FUSI gate electrode 24A and the sidewalls 9A exposed out of the first underlayer insulating film 12 in the n-type MIS transistor region Rn, as well as the first interlayer insulating film 13 and the top surfaces of the first underlayer insulating film 12, the FUSI gate electrode 24B and the second sidewalls 9B exposed in the first interlayer insulating film 13 in the p-type MIS transistor region Rp. Then, a second resist film (not shown) having an opening corresponding to the p-type MIS transistor region Rp is formed on the second underlayer insulating film 17 by lithography. Using the second resist film as a mask, the second underlayer insulating film 17 is removed from the p-type MIS transistor region Rp by etching. Thus, the second underlayer insulating film 17 remains only in the n-type MIS transistor region Rn as shown in FIG. 9A. Thereafter, the second resist film is removed by ashing or the like.

Then, in the step shown in FIG. 9B, a 500 nm thick silicon oxide (NSG) film added with no impurities is formed by CVD as a second interlayer insulating film 14 on the entire surface of the second underlayer insulating film 17 in the n-type MIS transistor region Rn and the first interlayer insulating film 13 and the first underlayer insulating film 12, second sidewalls 9B and FUSI gate electrode 24B exposed in the first interlayer insulating film 13 in the p-type MIS transistor region Rp. Then, the top surface of the second interlayer insulating film 14 is planarized by CMP. After that, in the same manner as in the first embodiment, contact plugs 16A are formed in the second interlayer insulating film 14 to be connected to the silicide films 10a formed in the upper portions of the n-type source/drain regions 10A in the n-type MIS transistor region Rn, and at the same time, contact plugs 16B are formed in the second interlayer insulating film 14 and the first interlayer insulating film 13 to be connected to the silicide films 10b formed in the upper portions of the p-type source/drain regions 10B in the p-type MIS transistor region Rp. The second underlayer insulating film 17 functions as an etch stopper in the step of forming contact holes 14a in the second interlayer insulating film 14 in the n-type MIS transistor region Rn, while the first underlayer insulating film 12 functions as an etch stopper in the step of forming contact holes 14b in the first interlayer insulating film 13 in the p-type MIS transistor region Rp. Subsequently, metal interconnection (not shown) is formed on the second interlayer insulating film 14 provided with the contact plugs 16A and 16B to be connected to the contact plugs 16A and 16B.

According to the method for manufacturing the semiconductor device of the second embodiment described above, the second underlayer insulating film 17 which functions as an etch stopper and a stressor film having tensile stress is formed to cover the first underlayer insulating film 12, the second sidewalls 9A and the FUSI gate electrode 24A continuously in the n-type MIS transistor region Rn. Therefore, the second underlayer insulating film 17 applies the tensile stress to the channel region of the n-type MIS transistor 100A with high reliability. The tensile stress applied to the n-type MIS transistor 100A improves the current drivability of the n-type MIS transistor 100A.

In the second embodiment, the second underlayer insulating film 17 is selectively formed only on the n-type MIS transistor 100A. This is preferable because tensile stress strain as significant as that caused in the n-type MIS transistor 100A is not caused in the channel region in the p-type MIS transistor 100B.

In the second embodiment, the second underlayer insulating film 17 is completely removed from the p-type MIS transistor region Rp. However, the second underlayer insulating film 17 may remain in the p-type MIS transistor region Rp except regions for forming the contact plugs. In this case, the second underlayer insulating film 17 is formed on the first interlayer insulating film 13 above the p-type source/drain regions 10B. As the first underlayer insulating film 12 and the second underlayer insulating film 17 do not directly contact each other above the p-type source/drain regions 10B, the tensile stress of the second underlayer insulating film 17 applied to the channel region of the p-type MIS transistor 100B is not as significantly as the tensile stress applied to the channel region of the n-type MIS transistor 100A. In this case, the removal of the second underlayer insulating film 17 from the regions for forming the contact plugs in the p-the MIS transistor region Rp is preferably carried out before the formation of the second interlayer insulating film 14.

(First Modification of Second Embodiment)

Hereinafter, explanation of a first modification of the second embodiment of the present invention is provided with reference to the drawings.

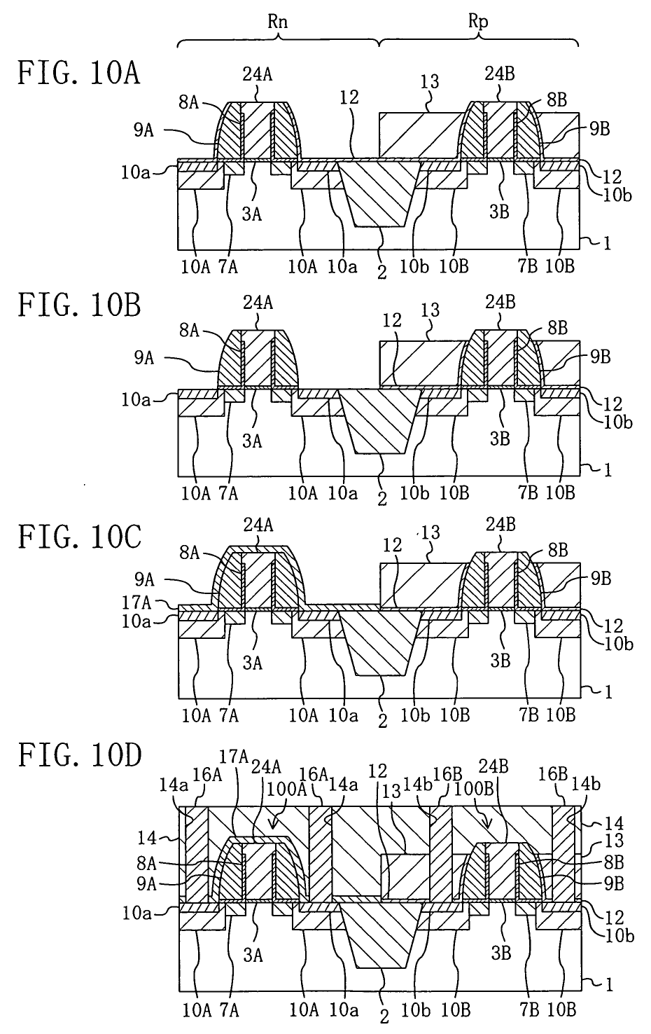

FIGS. 10A to 10D are sectional views illustrating the steps of a method for manufacturing a semiconductor device according to the first modification of the second embodiment of the present invention. In the following modifications, the same components as those shown in FIGS. 2 and 3 are indicated by the same reference numerals.

First, in the same manner as in the second embodiment, FUSI gate electrodes 24A and 24B are formed in the n-type MIS transistor region Rn and the p-type MIS transistor region Rp, respectively, and part of the first interlayer insulating film 13 formed in the n-type MIS transistor region Rn is selectively removed as shown in FIG. 10A.

Then, as shown in FIG. 10B, the first underlayer insulating film 12 is removed from the n-type MIS transistor region Rn by isotropic dry etching at a low etch rate using etching gas such as CF₄.

Then, a 20 nm thick silicon nitride film having tensile stress of 2 PGa is formed on the semiconductor substrate 1 by plasma CVD as a second underlayer insulating film 17A covering the silicide films 10a, the top surface of the FUSI gate electrode 24A, the top and side surfaces of the second sidewalls 9A and the end faces of the first sidewalls 8A in the n-type MIS transistor region Rn, as well as the first interlayer insulating film 13 and the surfaces of the first underlayer insulating film 12, FUSI gate electrode 24B and second sidewalls 9B exposed out of the first interlayer insulating film 13 in the p-type MIS transistor region Rp. Then, as shown in FIG. 10C, part of the second underlayer insulating film 17A formed in the p-type MIS transistor region Rp is removed by etching.

Then, in the same manner as in the second embodiment, a second interlayer insulating film 14 made of an NSG film is formed on the entire surface of the semiconductor substrate 1. Then, as shown in FIG. 10D, contact plugs 16A are formed in the second interlayer insulating film 14 in the n-type MIS transistor region Rn to be connected to the silicide films 10a, and at the same time, contact plugs 16B are formed in the second interlayer insulating film 14 and the first interlayer insulating film 13 in the p-type MIS transistor region Rp to be connected to the silicide films 10b.

Thus, with use of the second underlayer insulating film 17A continuously covering the n-type MIS transistor region Rn of the semiconductor substrate 1, the method of the first modification makes it possible to provide the same effect as obtained in the second embodiment.

(Second Modification of Second Embodiment)

Hereinafter, explanation of a second modification of the second embodiment of the present invention is provided with reference to the drawings.

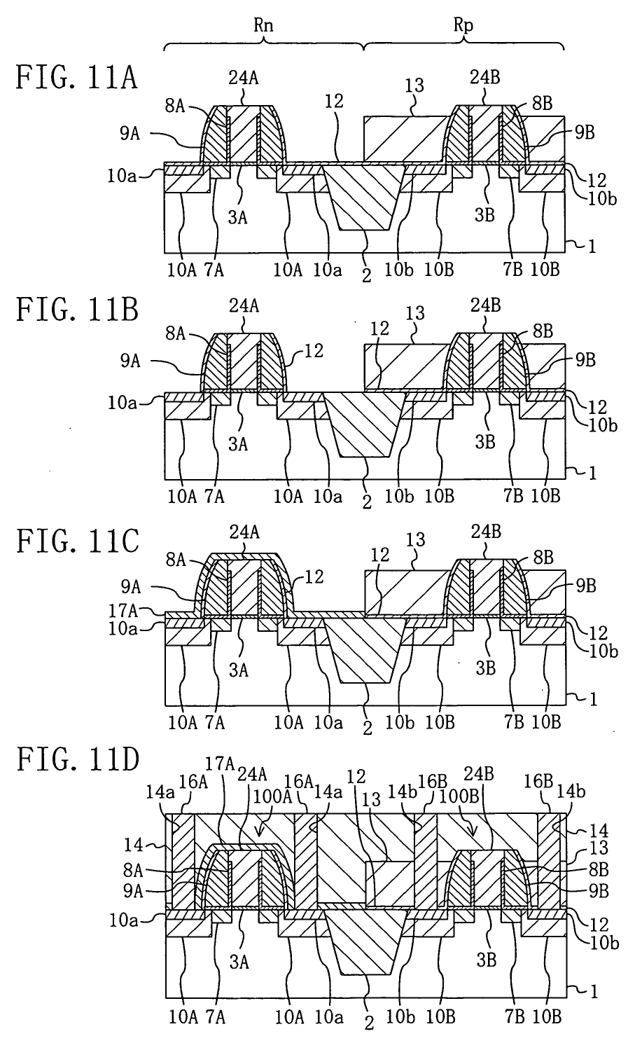

FIGS. 11A to 11D are sectional views illustrating the steps of a method for manufacturing a semiconductor device according to the second modification of the second embodiment of the present invention.

First, in the same manner as in the second embodiment, FUSI gate electrodes 24A and 24B are formed in the n-type MIS transistor region Rn and the p-type MIS transistor region Rp, respectively, and part of the first interlayer insulating film 13 formed in the n-type MIS transistor region Rn is selectively removed as shown in FIG. 11A.

Then, as shown in FIG. 11B, part of the first underlayer insulating film 12 in the n-type MIS transistor region Rn is removed by anisotropic etching using etching gas such as CHF₃ such that the first underlayer insulating film 12 remains on the side surfaces of the second sidewalls 9A.

Then, a 20 nm thick silicon nitride film having tensile stress of 2 PGa is formed on the semiconductor substrate 1 by plasma CVD as a second underlayer insulating film 17A covering the silicide films 10a, the surfaces of the FUSI gate electrode 24A, the second sidewalls 9A and the first underlayer insulating film 12 in the n-type MIS transistor region Rn, as well as the first interlayer insulating film 13 and the top surfaces of the first underlayer insulating film 12, the FUSI gate electrode 24B and the second sidewalls 9B in the p-type MIS transistor region Rp. Then, as shown in FIG. 11C, the second underlayer insulating film 17A is removed from the p-type MIS transistor region Rp by etching.

Then, as shown in FIG. 11D, in the same manner as in the second embodiment, a second interlayer insulating film 14 made of an NSG film is formed on the entire surface of the semiconductor substrate 1. Then, contact plugs 16A are formed in the second interlayer insulating film 14 in the n-type MIS transistor region Rn to be connected to the silicide films 10a formed in the upper portions of the n-type source/drain regions 10A, and at the same time, contact plugs 16B are formed in the second interlayer insulating film 14 and the first interlayer insulating film 13 in the p-type MIS transistor region Rp to be connected to the silicide films 10b formed in the upper portions of the p-type source/drain regions 10B.

Thus, with use of the second underlayer insulating film 17A continuously covering the n-type MIS transistor region Rn of the semiconductor substrate 1, the method of the second modification makes it possible to provide the same effect as obtained in the second embodiment.

(Third Modification of Second Embodiment)

Hereinafter, explanation of a third modification of the second embodiment of the present invention is provided.

In the third modification, the gate insulating film 3A in the n-type MIS transistor 100A and the gate insulating film 3B in the p-type MIS transistor 100B, both of which are made of silicon oxynitride, are replaced with high-k films in the same manner as in the third modification of the first embodiment.

In this case, after the step shown in FIG. 8C explained in the second embodiment, the thickness of the gate silicon film 4B in the p-type MIS transistor region Rp is reduced to 60 nm while the thickness of the gate silicon film 4A in the n-type MIS transistor Rn is kept to 100 nm. Then, the gate silicon films 4A and 4B are fully silicided to form FUSI gate electrodes 24A and 24C made of nickel silicide. The composition of the FUSI gate electrode 24A in the n-type MIS transistor region Rn is NiSi, while that of the FUSI gate electrode 24C in the p-type MIS transistor region Rp is Ni₃Si.

Thus, in the third modification, the effect obtained in the second embodiment is also achieved and the electric property of the p-type MIS transistor 100B, i.e., a threshold voltage, is controlled as required.

In the first and second embodiments and their modifications, the first underlayer insulating film 12 and the second underlayer insulating films 17 and 17A having tensile stress are formed by plasma CVD. However, low pressure CVD (LP-CVD) may be used to form these films.

As described above, the semiconductor device and the method for manufacturing the same according to the present invention make it possible to form a stressor film effectively even in a semiconductor device having FUSI gate electrodes, thereby improving the electric property of the semiconductor device. Thus, the present invention is useful for a semiconductor device having the FUSI gate electrodes and a method for manufacturing the same.

What is claimed is:

1. A semiconductor device comprising a first MIS transistor of a first conductivity type formed in a first region of a semiconductor region, wherein
the first MIS transistor includes:
a first gate insulating film formed on the first region;
a first gate electrode formed on the first gate insulating film and fully silicided with metal;
first source/drain regions formed in parts of the first region on the sides of the first gate electrode; and
an insulating film formed to cover the first gate electrode and the first source/drain regions to cause stress strain in part of the first region below the first gate electrode.

2. The semiconductor device of claim 1 further comprising a second MIS transistor of a second conductivity type formed in a second region of the semiconductor region, wherein
the second MIS transistor includes:
a second gate insulating film formed on the second region;
a second gate electrode formed on the second gate insulating film and fully silicided with metal;
second source/drain regions formed in parts of the second region on the sides of the second gate electrode; and
the insulating film formed to cover at least the second source/drain regions.

3. The semiconductor device of claim 2, wherein
the first conductivity type is an n-type and the second conductivity type is a p-type and the stress strain is tensile stress strain.

4. The semiconductor device of claim 2, wherein
the first gate electrode and the second gate electrode have the same silicide composition.

5. The semiconductor device of claim 4, wherein
the first gate insulating film and the second gate insulating film are principally made of silicon, oxygen and nitrogen.

6. The semiconductor device of claim 2, wherein
the first gate electrode and the second gate electrode have silicide compositions different from each other and the first gate insulating film and the second gate insulating film are made of a high dielectric substance.

7. The semiconductor device of claim 2, wherein
the insulating film also covers the top surface of the second gate electrode.

8. The semiconductor device of claim 2, wherein
the insulating film includes a first insulating film and a second insulating film,
only the second insulating film of the first and second insulating films is formed on the first gate electrode and the second gate electrode and
both of the first and second insulating films are formed in this order on the first source/drain regions and the second source/drain regions.

9. The semiconductor device of claim 2 further comprising:
first sidewalls formed on the side surfaces of the first gate electrode; and
second sidewalls formed on the side surfaces of the second gate electrode, wherein
the insulating film includes a first insulating film and a second insulating film,
only the second insulating film of the first and second insulating films is formed on the first gate electrode and the second gate electrode,
only the second insulating film of the first and second insulating films is formed on the first source/drain regions and the second source/drain regions and
both of the first and second insulating films are formed in this order on the side surfaces of the first sidewalls and the second sidewalls.

10. The semiconductor device of claim 2, wherein
the insulating film is not formed on the second gate electrode.

11. The semiconductor device of claim 2, wherein
the insulating film includes a first insulating film and a second insulating film,
only the second insulating film of the first and second insulating films is formed on the first gate electrode,
both of the first and second insulating films are formed in this order on the first source/drain regions and
only the first insulating film of the first and second insulating films is formed on the second source/drain regions.

12. The semiconductor device of claim 2, wherein
the insulating film includes a first insulating film and a second insulating film thinner than the first insulating film,
only the first insulating film of the first and second insulating films is formed on the first gate electrode and the first source/drain regions and
only the second insulating film of the first and second insulating films is formed on the second source/drain regions.

13. The semiconductor device of claim 2 further comprising:
first sidewalls formed on the side surfaces of the first gate electrode; and
second sidewalls formed on the side surfaces of the second gate electrode, wherein
the insulating film includes a first insulating film and a second insulating film thinner than the first insulating film,
only the first insulating film of the first and second insulating films is formed on the first gate electrode and the first source/drain regions,
both of the second and first insulating films are formed in this order on the side surfaces of the first sidewalls and
only the second insulating film of the first and second insulating films is formed on the second source/drain regions and the side surfaces of the second sidewalls.

14. The semiconductor device of claim 2, wherein
an interlayer insulating film is formed on the second source/drain regions with the insulating film interposed therebetween and
the interlayer insulating film is not formed on the first source/drain regions.

15. The semiconductor device of claim 1, wherein
the insulating film includes a first insulating film and a second insulating film,
only the second insulating film of the first and second insulating films is formed on the first gate electrode and
both of the first and second insulating films are formed in this order on the first source/drain regions.

16. A method for manufacturing a semiconductor device comprising the steps of:
(a) forming a first gate insulating film on a first region of a semiconductor region;
(b) forming a first gate silicon film having a gate pattern on the first gate insulating film;
(c) forming first source/drain regions of a first conductivity type in parts of the first region on the sides of the first gate silicon film;
(d) depositing a first metal film on the first gate silicon film and performing heat treatment after the step (c) such that the first gate silicon film is fully silicided with the first metal film to become a first gate electrode; and
(e) forming an insulating film on the first gate electrode and the first source/drain regions to cause stress strain in the first region.

17. The method of claim 16, wherein
a second gate insulating film is formed on a second region of the semiconductor region in the step (a),
a second gate silicon film having a gate pattern is formed on the second gate insulating film in the step (b),
the step (c) includes the step of forming second source/drain regions in parts of the second region on the sides of the second gate silicon film and
the first metal film is deposited on the second gate silicon film and heat treatment is performed in the step (d) such that the second gate silicon film is fully silicided with the first metal to become a second gate electrode.

18. The method of claim 17 further comprising:
the steps of (f) forming a first insulating film on the first region and the second region to cause stress strain in the first region; and (g) removing parts of the first insulating film on the first gate silicon film and the second gate silicon film to be performed between the steps (c) and (d), wherein
a second insulating film serving as the insulating film is formed in the step (e) to cover the first gate electrode, the second gate electrode, the first source/drain regions and the second source/drain regions.

19. The method of claim 17 further comprising:
the steps of (f) forming a first insulating film on the first region and the second region to cause stress strain in the first region and (g) removing parts of the first insulating film on the first gate silicon film and the second gate silicon film to be performed between the steps (c) and (d); and
the step of (h) removing parts of the first insulating film on the first region and the second region to be performed between the steps (d) and (e), wherein
a second insulating film serving as the insulating film is formed in the step (e) to cover the first gate electrode, the second gate electrode, the first source/drain regions and the second source/drain regions.

20. The method of claim 17 further comprising:
the step of (f) forming first sidewalls on the side surfaces of the first gate silicon film and second sidewalls on the side surfaces of the second gate silicon film to be performed between the steps (b) and (c);
the steps of (g) forming a first insulating film on the first region and the second region to cause stress strain in the first region and (h) removing parts of the first insulating film on the first gate silicon film and the second gate silicon film to be performed between the steps (c) and (d); and
the step of (i) removing parts of the first insulating film on the first source/drain regions and the second source/drain regions such that the first insulating film remains on the side surfaces of the first sidewalls and the second sidewalls to be performed between the steps (d) and (e), wherein
a second insulating film serving as the insulating film is formed in the step (e) to cover the first gate electrode, the second gate electrode, the first source/drain regions and the second source/drain regions.

21. The method of claim 17 further comprising:
the steps of (f) forming a first insulating film on the first region and the second region to cause stress strain in the first region and forming an interlayer insulating film on the first insulating film, (g) removing parts of the first insulating film and parts of the interlayer insulating film on the first gate silicon film and the second gate silicon film and (h) removing part of the interlayer insulating film on the first region after the step (g) to be performed between the steps (c) and (d), wherein
a second insulating film is formed on the first region and the second region and part of the second insulating film formed on the second region is removed in the step (e) to provide the insulating film made of the second insulating film.

22. The method of claim 17 further comprising:
the steps of (f) forming a first insulating film on the first region and the second region to cause stress strain in the first region and forming an interlayer insulating film on the first insulating film, (g) removing parts of the first insulating film and the interlayer insulating film on the first gate silicon film and the second gate silicon film and (h) removing parts of the first insulating film and the interlayer insulating film on the first region after the step (g) to be performed between the steps (c) and (d), wherein
a second insulating film is formed on the first region and the second region and part of the second insulating film formed on the second region is removed in the step (e) to provide the insulating film made of the second insulating film.

23. The method of claim 17 further comprising:
the step of (f) forming first sidewalls on the side surfaces of the first gate silicon film and second sidewalls on the side surfaces of the second gate silicon film to be performed between the steps (b) and (c); and
the steps of (g) forming a first insulating film on the first region and the second region to cause stress strain in the first region and forming an interlayer insulating film on the first insulating film, (h) removing parts of the first insulating film and the interlayer insulating film on the first gate silicon film and the second gate silicon film, (i) removing part of the interlayer insulating film on the first region after the step (h) and (j) removing part of the first insulating film on the first source/drain regions after the step (i) such that the first insulating film remains on the side surfaces of the first sidewalls to be performed between the steps (c) and (d), wherein
a second insulating film is formed on the first region and the second region and part of the second insulating film formed on the second region is removed in the step (e) to provide the insulating film made of the second insulating film.
